(19) United States
(12) Patent Application Publication
(10) Pub. No.: US 2026/0299020 A1
(43) Pub. Date: Oct. 1, 2026

(54) JTAG-BASED SOC DESIGN VERIFICATION ON EMULATION

(71) Applicant: Microsoft Technology Licensing, LLC, Redmond, WA (US)

(72) Inventors: Dibyendu DEY, Portland, OR (US); Cameron Doran WILDE, Hillsboro, OR (US); Gary Steven SINGER, Raleigh, NC (US); Sarah Skye TISDALE, Hillsboro, OR (US); Suresh DUTHIRARU, Portland, OR (US)

(21) Appl. No.: 19/091,061

(22) Filed: Mar. 26, 2025

(51) Int. Cl. G01R 31/317; G01R 31/3183; G01R 31/3185

(52) U.S. Cl. CPC G01R 31/31704; G01R 31/318307; G01R 31/318533

(57) ABSTRACT

The described technology provides a method including generating a register database, wherein the register database is configured to store one or more parameters of a plurality of registers, the plurality of registers representing the registers for a plurality of functional components on a system on chip (SoC), receiving a design verification flow for verifying one or more of the plurality of functional components on the SOC, generating a design verification script based on design verification flow, converting the design verification script into a series of JTAG transactions, and executing the series of JTAG transactions using a JTAG transactor.

### BACKGROUND

Computing systems may be implemented on system on chips (SoCs) which are a type of integrated circuit (IC) design that combines many or all high-level functional elements of an electronic device onto a single chip instead of using separate components mounted to a motherboard, as is done in traditional electronics design. Typical SoCs may include a number of functional blocks, such as processors, memory units, I/O units, communication units, etc., each having a number of registers having a number of fields. Registers constitute a significant percentage of today's complex SoC designs and make up a significant portion of today's complex SoC designs. For example, in modern SoCs, the number of registers can range into the millions or sometimes into tens of millions. Specifically, on-chip registers define interface to the hardware elements on the SoCs and usually represent a large portion of the device specification and programmer's guide.

### SUMMARY

The described technology provides a method including generating a register database, wherein the register database is configured to store one or more parameters of a plurality of registers, the plurality of registers representing the registers for a plurality of functional components on a system on chip (SoC), receiving a design verification flow for verifying one or more of the plurality of functional components on the SOC, generating a design verification script based on design verification flow, converting the design verification script into a series of Joint Test Action Group (JTAG) transactions, and executing the series of JTAG transactions using a JTAG transactor.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Other implementations are also described and recited herein.

### BRIEF DESCRIPTIONS OF THE DRAWINGS

FIG. 1 illustrates an example implementation of SOC design lifecycle using JTAG based design verification and emulation as disclosed herein.

FIG. 2 illustrates an alternative example representation of emulation prototypes for SoC functional components.

FIG. 3 illustrates an example process of extracting and organizing design information into a database.

FIG. 4 illustrates an alternative example process by which verification flow is transformed into a sequence of register read/write transactions.

FIG. 5 illustrates alternative example operations of transforming design verification process into register transactions.

FIG. 6 illustrates alternative example operations of the system for providing SoC design verification and emulation as disclosed herein.

FIG. 7 illustrates an example system that may be useful in implementing the collaboration network mining technology disclosed herein.

### DETAILED DESCRIPTIONS

Modern system-on-chip (SoC) designs comprise multiple functional components, making design verification (DV) essential for achieving successful design goals. The DV may be performed through simulation of the SoC and its individual functional components. However, this simulation process is time-consuming, resource-intensive, and requires substantial engineering hours.

The implementations of the system for providing SoC design verification and emulation as disclosed herein provide validating functional blocks in integrated circuits (ICs) utilizing emulation-based JTAG transactions. Here JTAG (named after the Joint Test Action Group which codified it) refers to the industry standard for verifying designs of and testing printed circuit boards. Specifically, the system disclosed herein achieves this end-to-end goal by abstracting each register space into a component. The system adds the abstracted component is added to a database. Subsequently, the system integrates a software-based JTAG hook into an emulation environment. This enables enabling the conversion of any design validation flow into register object transactions using any software language.

The system for SoC design verification and emulation as disclosed herein provides a technical advantage by simplifying the re-writing of design validation scripts. Furthermore, it also improves execution performance by leveraging the speed of the emulation platform and allows for easy searching of specific address spaces by querying the database. Additionally, the system for SoC design verification and emulation as disclosed herein provides a technical advantage because it supports the use of API features incorporated in the validation script that utilizes the cloud-based database. Furthermore, the system for SoC design verification and emulation as disclosed herein provides a technical advantage as it reduces validation time by order of magnitude and paves the way for advancing the speed and efficiency of design validation.

In SoCs, functional unit blocks may be replicated to build larger blocks. These functional unit blocks have similar registers with addresses relative to their joint test action group (JTAG) endpoint. Register group definitions may include a pattern of the register name and discover similar registers so that they can be programmed as a group instead of individually.

An implementation disclosed herein provides a method including generating a register database, wherein the register database is configured to store one or more parameters of a plurality of registers, the plurality of registers representing the registers for a plurality of functional components on a system on chip (SoC), receiving a design verification flow for verifying one or more of the plurality of functional components on the SOC, generating a design verification script based on design verification flow, converting the design verification script into a series of JTAG transactions, and executing the series of JTAG transactions using a JTAG transactor.

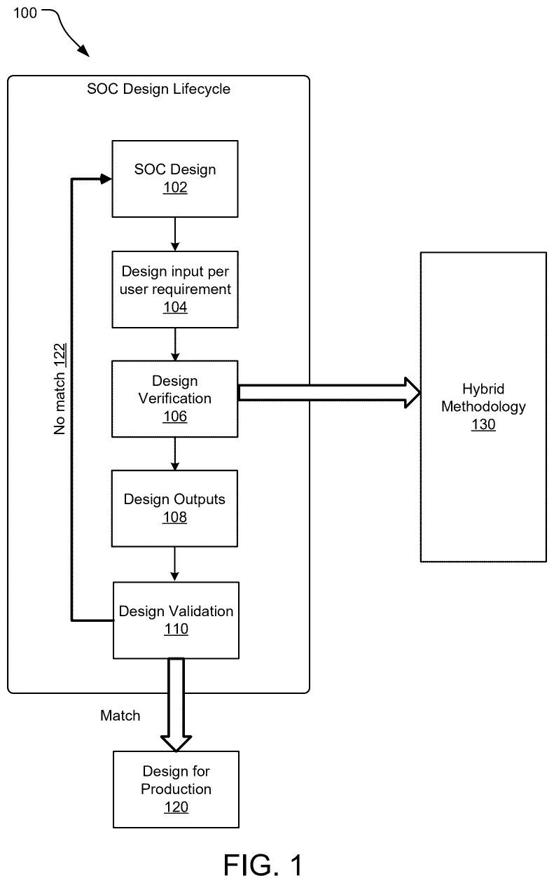

Now referring to the specific implementations, FIG. 1 illustrates an implementation of the SOC design lifecycle 100 using JTAG based design verification and emulation as disclosed herein. At 102, an SOC design architect determines the specific SOC design and architecture of the SOC. The design may include the list of functional components that are to be SOC, interconnections between the functional components, etc. Subsequently, at 104, various inputs into the SOC and the functional components are determined.

At 106, the SOC design and the input are verified. In the illustrated implementation, the design verification is performed using a hybrid methodology 130, as further disclosed by various implementations herein. Specifically, the hybrid methodology 130 leverages JTAG based design verification on emulation through a combined hardware-software methodology. Specifically, the hybrid methodology 130 uses JTAG based verification on emulation.

The illustrated implementations harness the benefits of both emulation and design verification, thus allowing access to complex full SOC design while achieving the results much faster compared to other methods, such as simulation. Furthermore, in alternative implementation the hybrid methodology 130 that used JTAG based design can also use FPGA prototyping to perform design verification. Also, the hybrid methodology 130 addresses many design verification problems.

Once verified, at 108, various SOC design outputs are generated. The SOC design outputs are validated at 110. Specifically, the verifications include ascertaining that the SOC design and the inputs match the specific requirements of the customers. If the SOC design is validated, in that the SOC design and the input specifications match the customer requirements, at 102, the validated design is submitted for production at 120. If there is no match, as per 122, the design lifecycle 100 may be repeated.

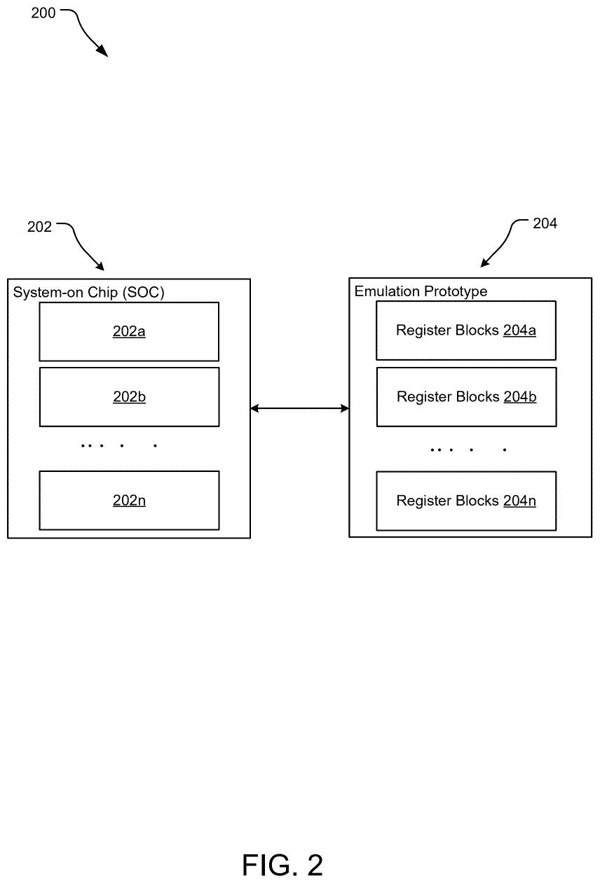

FIG. 2 illustrates an SOC representation 200 of emulation prototypes for SoC functional components in the manner disclosed herein. Specifically, the SOC representation 200 includes an SOC 202 including a number of functional components 202a-202n. Also illustrated is an emulation prototype 204 of the SOC 202. Specifically, the emulation prototype 204 includes a number of register blocks 204a-204n. Each of the register blocks 204a-204n may emulate one of the functional components 202a-202n. For example, the register blocks 202a may emulate the functional component 202a, the register blocks 202b may emulate the functional component 202b, etc.

In one implementation, the emulation prototype 204 is a hardware prototype that is configured using FPGAs. The content stored on the register blocks 204a-204n of the emulation prototype 204 may be accessed using software.

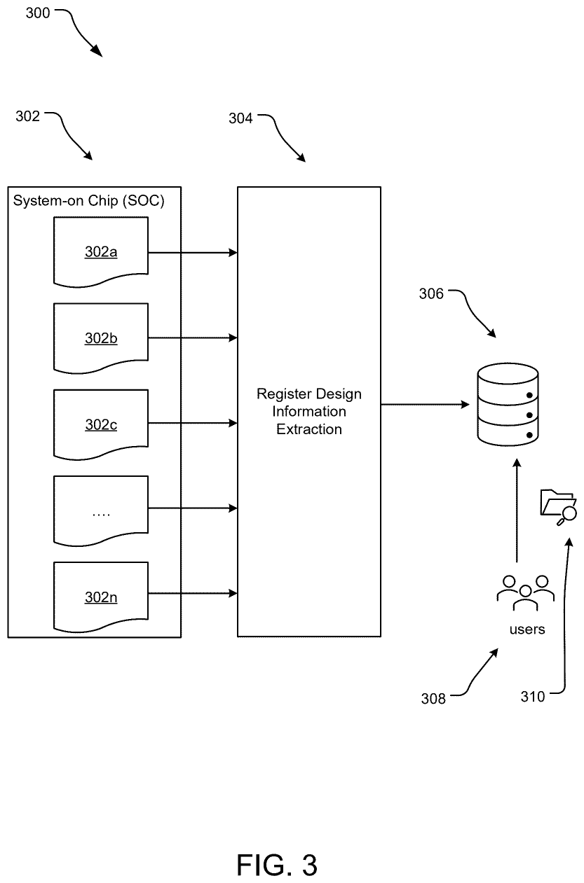

FIG. 3 illustrates a process 300 of extracting or harvesting and organizing design information into a database 306. As illustrated an SOC 302 may have a number of functional components 302a-302n. A register design information extraction (RDIE) engine 304 communicates with the SOC 302 and extracts information about the various functional components 302. The extracted information is stored in the database 306, which is accessible to users 308. For example, the database 306 may include information about each functional component 302 such as the registers on the functional component 302, their addresses, their default values, etc. Specifically, the RDIE engine 304 extracts all information about the functional components 302a-302n that may be required for the verification of the SOC 302 and stores it into the database 306.

The users 308 may query the database 306 directly, thus bypassing the need to search through design documentation 310. For example, the users 308 may search for specific registers using design-related information or strings. For example, searching for ‘component_{A} memory register’ may provide a series of related registers corresponding to the component_{A} cache. This approach enables the identification of registers used in the design verification flow.

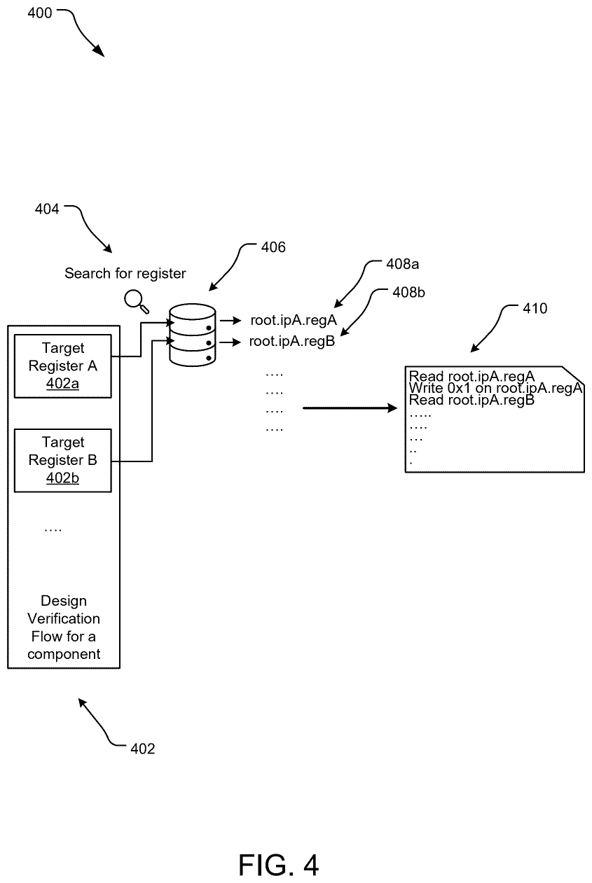

FIG. 4 illustrates a process 400 by which verification flow is transformed into a sequence of register read/write transactions. Specifically, the process 400 illustrates converting design verification flow 402 that may be used to verify various target registers into verification script 410. For example, the design verification flow 402 may include design verification flow for a target register A 402a, and target register B 402b of a functional component.

For example, the design verification flow for the target register A 402a include searching for the register 408a in a register database 406. The register database 406 may be a database that is created as illustrated in FIG. 3 by extracting information about various functional components in the SOC. Such a register database 406 may include names of the registers, various parameters of these registers such as their size in number of bits, their default values, their JTAG addresses, etc. For example, in one implementation, the register database 406 may store information about each register including its root level, its node, and its fields. Furthermore, any time a new functional block is added to the SoC, the register database 406 is updated to include the above information about all the registers of the newly added functional component. In this manner, the register database 406 is dynamic in that it maintains up to date information about all the registers.

In an illustrated implementation, the register database 406 may store information such as default values, etc., about the target register A 402a at root.ipA.regA 408a. Similarly, the register database 406 may store information such as default values, etc., about the target register b 402b at root.ipA.regB 408b, etc. Here the root.ipA.regA 408a, root.ipA.regB represent abstractions of the target register A 402a and the target register B 402b.

The design verification flow 402 may include various verification steps including reading the value from the root.ipA.regA 408a, writing 0x1 onto the root.ipA.regA 408a, reading the value from the root.ipA.regB 408 b, etc. As illustrated these steps are stored into the verification script 410. Subsequently, the verification script 410 may be run using JTAG instructions to verify the functional component and its target registers 402a, 402b, etc.

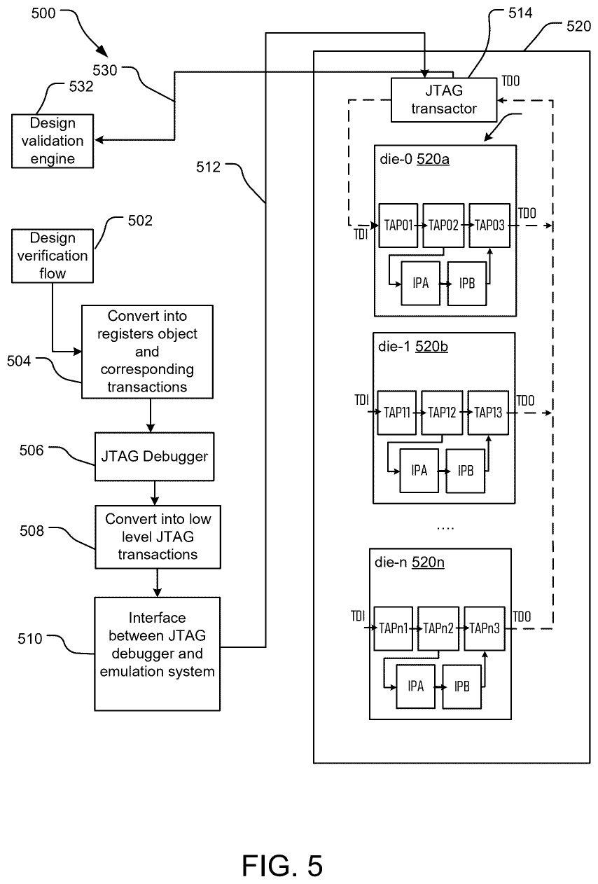

FIG. 5 illustrates operations 500 of transforming design verification process into register transactions, which then interacts with an emulation model to execute JTAG-based transactions. Specifically, an operation 504 converts a design verification flow 502 into registers objects and corresponding transactions. The output of the operation 504 may a verification script, such the verification script 410 illustrated in FIG. 3. Subsequently, the verification script is input into a JTAG debugger 506 which at 508 converts the verification script into low level JTAG transactions.

The low level JTAG transactions are, for example, assembly level instructions that can be executed by a JTAG transactor. An interface 510 between the JTAG debugger and an emulation model provides virtual JTAG access 512 to a JTAG transactor 514. Specifically, the JTAG transactor 514 may be configured in a design under test (DUT) emulation model 520. The DUT emulation model 520 may include die level emulators 520a-520n for various dies that are configured to receive JTAG instructions from the JTAG transactor 514.

For example, the JTAG transactor 524 may input test data (TDI) into the die level emulators 520a-520n and receive the output test data (TDO). In one implementation, each of the die level emulators 520a-520n may be configured using FPGAs. Various read, write, assertion commands from the verification script are thus run through the DUT emulation model 520 and the outputs TDOs from the various emulators are evaluated to perform verification of the SOC that is emulated by the DUT emulation model 520. Specifically, as shown at 530, various outputs TDOs are communicated back from the JTAG transactor 514 to a design validation engine 532, which may evaluate the TDO values to determine if the verification is successful or not. For example, the design validation engine 532 may ascertain that the SOC design and the inputs match the specific requirements of the customers. If the SOC design is validated, in that the SOC design and the input specifications match the customer requirements, the validated design is submitted for production. If there is no match, the design lifecycle may be repeated.

The process 500 may be used to address various problems such as injection of code into core memory of an SOC and execution of the code. Also, the process 500 may be used to load binary files into various functional components of the SOC, for loading and running assembly code into the SOC, etc.

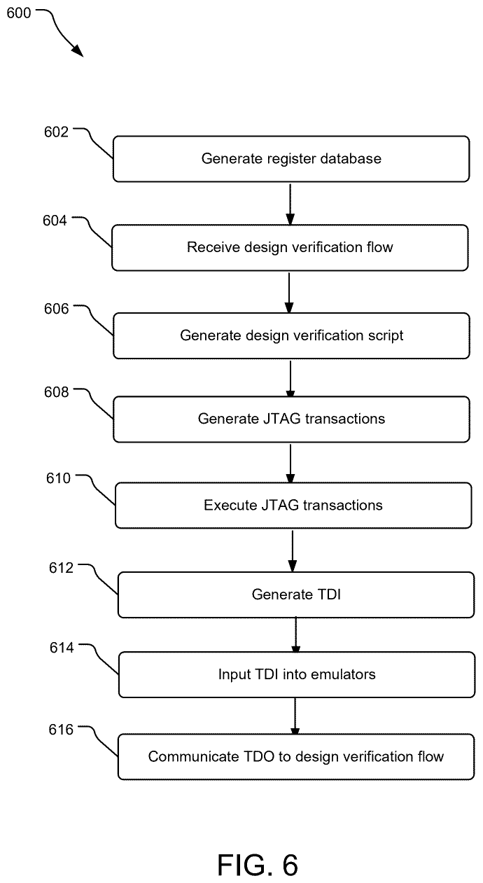

FIG. 6 illustrates operations 600 of the system for providing SoC design verification and emulation as disclosed herein. An operation 602 generates a register database. For example, the register database may be a database that is created as illustrated in FIG. 3 by extracting information about various functional components in the SOC.

An operation 604 receives a design verification flow. The design verification flow may include a series of commands for verifying one or more functional components on the SOC. For example, the design verification flow may include a command for verifying the value of a target register, for verifying a default status of another target register, etc. An operation 606 parses the design verification flow to generate a design verification script. Specifically, based on the verification flow for specific use cases, such as general debugging examples like injecting code into memory or trace propagation through the embedded trace buffer and router, these operations may be performed through a series of control/status register (CSR) operations. For example, parsing may include decomposing a debug example into a series of CSR transactions. Here, the debug scenario is first broken down into atomic steps of possible CSR transactions. Subsequently, the information is searched in the built register database to identify the corresponding CSR, and based on that, the transaction is created. Subsequently, the system assembles these transactions section by section to build the entire debug flow, which can be executed on emulation over the JTAG transport.

Subsequently, an operation 608 generates a series of JTAG transactions based on the design verification script. At operation 610, the JTAG transactions are executed using a JTAG transactor. Specifically, as a result of executing the JTAG transactions, an operation 612 generates input test data (TDI) based on one or more of the JTAG transactions. The TDI is input into one of the die-level emulators at operation 614. Subsequently at operation 616, the test data out (TDO) received from the one of the plurality of die-level emulators in response to the TDI is communicated to a design validation engine.

The abstraction used by the system for SoC design verification and emulation as disclosed herein provides a technical advantage by removing the complexity in design validation and increases the durability of tasks. Additionally, such abstraction also provides search capability, thus simplifying the conversion of design validation flows into higher-level software languages. As a result, the system for SoC design verification and emulation as disclosed herein provides a technical advantage by performing design validation more quickly compared to simulation. Additionally, the system for SoC design verification and emulation as disclosed herein uses low level JTAG transaction, which provides technical advantage in that is enables an option to perform low-level JTAG transactions in an emulation environment.

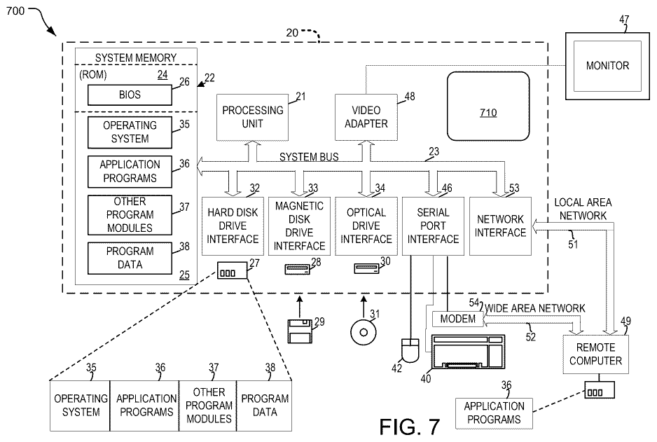

FIG. 7 illustrates an example system 700 that may be useful in implementing the system for providing SOC design verification on emulation disclosed herein. The example hardware and operating environment of FIG. 7 for implementing the described technology includes a computing device, such as a general-purpose computing device in the form of a computer 20, a mobile telephone, a personal data assistant (PDA), a tablet, smart watch, gaming remote, or other type of computing device. In the implementation of FIG. 7, for example, the computer 20 includes a processing unit 21, a system memory 22, and a system bus 23 that operatively couples various system components, including the system memory 22 to the processing unit 21. There may be only one or there may be more than one processing units 21, such that the processor of a computer 20 comprises a single central-processing unit (CPU), or a plurality of processing units, commonly referred to as a parallel processing environment. The computer 20 may be a conventional computer, a distributed computer, or any other type of computer; the implementations are not so limited.

The system bus 23 may be any of several types of bus structures, including a memory bus or memory controller, a peripheral bus, a switched fabric, point-to-point connections, and a local bus using any of a variety of bus architectures. The system memory 22 may also be referred to as simply the memory and includes read-only memory (ROM) 24 and random-access memory (RAM) 25. A basic input/output system (BIOS) 26, contains the basic routines that help to transfer information between elements within the computer 20, such as during start-up, is stored in ROM 24. The computer 20 further includes a hard disk drive 27 for reading from and writing to a hard disk, not shown, a magnetic disk drive 28 for reading from or writing to a removable magnetic disk 29, and an optical disk drive 30 for reading from or writing to a removable optical disk 31 such as a CD ROM, DVD, or other optical media.

The computer 20 may be used to implement a high latency query optimization system disclosed herein. In one implementation, a frequency unwrapping module, including instructions to unwrap frequencies based at least in part on the sampled reflected modulations signals, may be stored in memory of the computer 20, such as the read-only memory (ROM) 24 and random-access memory (RAM) 25.

Furthermore, instructions stored on the memory of the computer 20 may be used to generate a transformation matrix using one or more operations disclosed in FIG. 7. Similarly, instructions stored on the memory of the computer 20 may also be used to implement one or more operations of FIG. 1. The memory of the computer 20 may also one or more instructions to implement the high latency query optimization system disclosed herein.

The hard disk drive 27, magnetic disk drive 28, and optical disk drive 30 are connected to the system bus 23 by a hard disk drive interface 32, a magnetic disk drive interface 33, and an optical disk drive interface 34, respectively. The drives and their associated tangible computer-readable media provide non-volatile storage of computer-readable instructions, data structures, program modules and other data for the computer 20. It should be appreciated by those skilled in the art that any type of tangible computer-readable media may be used in the example operating environment.

A number of program modules may be stored on the hard disk, magnetic disk 29, optical disk 31, ROM 24, or RAM 25, including an operating system 35, one or more application programs 36, other program modules 37, and program data 38. A user may generate reminders on the personal computer 20 through input devices such as a keyboard 40 and pointing device 42. Other input devices (not shown) may include a microphone (e.g., for voice input), a camera (e.g., for a natural user interface (NUI)), a joystick, a game pad, a satellite dish, a scanner, or the like. These and other input devices are often connected to the processing unit 21 through a serial port interface 46 that is coupled to the system bus 23, but may be connected by other interfaces, such as a parallel port, game port, or a universal serial bus (USB). A monitor 47 or other type of display device is also connected to the system bus 23 via an interface, such as a video adapter 48. In addition to the monitor, computers typically include other peripheral output devices (not shown), such as speakers and printers.

The computer 20 may operate in a networked environment using logical connections to one or more remote computers, such as remote computer 49. These logical connections are achieved by a communication device coupled to or a part of the computer 20; the implementations are not limited to a particular type of communications device. The remote computer 49 may be another computer, a server, a router, a network PC, a client, a peer device, or other common network node, and typically includes many or all of the elements described above relative to the computer 20. The logical connections depicted in FIG. 7 include a local-area network (LAN) 51 and a wide-area network (WAN) 52. Such networking environments are commonplace in office networks, enterprise-wide computer networks, intranets, and the Internet, which are all types of networks.

When used in a LAN-networking environment, the computer 20 is connected to the local area network 51 through a network interface or adapter 53, which is one type of communications device. When used in a WAN-networking environment, the computer 20 typically includes a modem 54, a network adapter, a type of communications device, or any other type of communications device for establishing communications over the wide area network 52. The modem 54, which may be internal or external, is connected to the system bus 23 via the serial port interface 46. In a networked environment, program engines depicted relative to the personal computer 20, or portions thereof, may be stored in the remote memory storage device. It is appreciated that the network connections shown are example and other means of communications devices for establishing a communications link between the computers may be used.

In an example implementation, software, or firmware instructions for the system 710 for providing SOC design verification on emulation may be stored in system memory 22 and/or storage devices 29 or 31 and processed by the processing unit 21. high latency query optimization system operations and data may be stored in system memory 22 and/or storage devices 29 or 31 as persistent data-stores.

In contrast to tangible computer-readable storage media, intangible computer-readable communication signals may embody computer readable instructions, data structures, program modules or other data resident in a modulated data signal, such as a carrier wave or other signal transport mechanism. The term “modulated data signal” means a signal that has one or more of its characteristics set or changed in such a manner as to encode information in the signal. By way of example, and not limitation, intangible communication signals include wired media such as a wired network or direct-wired connection, and wireless media such as acoustic, RF, infrared and other wireless media.

Some embodiments of high latency query optimization system may comprise an article of manufacture. An article of manufacture may comprise a tangible storage medium to store logic. Examples of a storage medium may include one or more types of computer-readable storage media capable of storing electronic data, including volatile memory or non-volatile memory, removable or non-removable memory, erasable or non-erasable memory, writeable or re-writeable memory, and so forth. Examples of the logic may include various software elements, such as software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. In one embodiment, for example, an article of manufacture may store executable computer program instructions that, when executed by a computer, cause the computer to perform methods and/or operations in accordance with the described embodiments. The executable computer program instructions may include any suitable type of code, such as source code, compiled code, interpreted code, executable code, static code, dynamic code, and the like. The executable computer program instructions may be implemented according to a predefined computer language, manner, or syntax, for instructing a computer to perform a certain function. The instructions may be implemented using any suitable high-level, low-level, object-oriented, visual, compiled and/or interpreted programming language.

The high latency query optimization system disclosed herein may include a variety of tangible computer-readable storage media and intangible computer-readable communication signals. Tangible computer-readable storage can be embodied by any available media that can be accessed by the high latency query optimization system disclosed herein and includes both volatile and nonvolatile storage media, removable and non-removable storage media. Tangible computer-readable storage media excludes intangible and transitory communications signals and includes volatile and nonvolatile, removable, and non-removable storage media implemented in any method or technology for storage of information such as computer readable instructions, data structures, program modules or other data. Tangible computer-readable storage media includes, but is not limited to, RAM, ROM, EEPROM, flash memory or other memory technology, CDROM, digital versatile disks (DVD) or other optical disk storage, magnetic cassettes, magnetic tape, magnetic disk storage or other magnetic storage devices, or any other tangible medium which can be used to store the desired information, and which can be accessed by the high latency query optimization system disclosed herein. In contrast to tangible computer-readable storage media, intangible computer-readable communication signals may embody computer readable instructions, data structures, program modules or other data resident in a modulated data signal, such as a carrier wave or other signal transport mechanism. The term “modulated data signal” means a signal that has one or more of its characteristics set or changed in such a manner as to encode information in the signal. By way of example, and not limitation, intangible communication signals include signals moving through wired media such as a wired network or direct-wired connection, and signals moving through wireless media such as acoustic, RF, infrared and other wireless media.

An implementation disclosed herein provides a method including determining a plurality of blocks configured on a system on chip (SoC), generating a register database, wherein the register database is configured to store one or more parameters of a plurality of registers, the plurality of registers representing the registers for a plurality of blocks the SoC, determining one or more pattern strings, wherein each of the strings identify a common functionality among a plurality of registers, performing a search on a register database for identifying a group of registers from the plurality of registers, wherein names of each of the group of registers include the pattern string, and generating a virtual register that relates to the group of registers.

In another implementation, a system disclosed herein includes a memory, one or more processing units, and a register grouping system stored in the memory and executable by the one or more processor units, the register grouping system encoding computer-executable instructions on the memory for executing on the one or more processor units a computer process, the computer process including generating a register database, wherein the register database is configured to store one or more parameters of a plurality of registers, the plurality of registers representing the registers for a plurality of blocks the SoC, determining one or more pattern strings, wherein each of the strings identify a common functionality among a plurality of registers, performing a search on a register database for identifying a group of registers from the plurality of registers, wherein names of each of the group of registers include the pattern string, and generating a virtual register that relates to the group of registers.

Another implementation includes one or more physically manufactured computer-readable storage media, encoding computer-executable instructions for executing on a computer system a computer process, the computer process including generating a register database, wherein the register database is configured to store one or more parameters of a plurality of registers, the plurality of registers representing the registers for a plurality of blocks the SoC, determining one or more pattern strings, wherein each of the strings identify a common functionality among a plurality of registers, performing a search on a register database for identifying a group of registers from the plurality of registers, wherein names of each of the group of registers include the pattern string, and generating a virtual register that relates to the group of registers.

The described technology provides a method including generating a register database, wherein the register database is configured to store one or more parameters of a plurality of registers, the plurality of registers representing the registers for a plurality of functional components on a system on chip (SoC), receiving a design verification flow for verifying one or more of the plurality of functional components on the SOC, generating a design verification script based on design verification flow, converting the design verification script into a series of JTAG transactions, and executing the series of JTAG transactions using a JTAG transactor.

An implementation discloses a system including a memory, one or more processing units, and a system on chip (SOC) design verification and emulation system stored in the memory and executable by the one or more processor units, the SOC design verification and emulation system encoding computer-executable instructions on the memory for executing on the one or more processor units a computer process, the computer process including generating a register database, wherein the register database is configured to store one or more parameters of a plurality of registers, the plurality of registers representing the registers for a plurality of functional components on a system on chip (SoC), receiving a design verification flow for verifying one or more of the plurality of functional components on the SOC, generating a design verification script based on design verification flow, converting the design verification script into a series of JTAG transactions, and executing the series of JTAG transactions using a JTAG transactor.

One or more physically manufactured computer-readable storage media, encoding computer-executable instructions for executing on a computer system a computer process, the computer process including generating a register database, wherein the register database is configured to store one or more parameters of a plurality of registers, the plurality of registers representing the registers for a plurality of functional components on a system on chip (SoC), receiving a design verification flow for verifying one or more of the plurality of functional components on the SOC, generating a design verification script based on design verification flow, converting the design verification script into a series of JTAG transactions, and executing the series of JTAG transactions using a JTAG transactor.

Implementations described herein are implemented as logical steps in one or more computer systems. The logical operations may be implemented (1) as a sequence of processor-implemented steps executing in one or more computer systems and (2) as interconnected machine or circuit modules within one or more computer systems. The implementation is a matter of choice, dependent on the performance requirements of the computer system being utilized. Accordingly, the logical operations making up the implementations described herein are referred to variously as operations, steps, objects, or modules. Furthermore, it should be understood that logical operations may be performed in any order, unless explicitly claimed otherwise or a specific order is inherently necessitated by the claim language. The above specification, examples, and data, together with the attached appendices, provide a complete description of the structure and use of exemplary implementations.

What is claimed is:

1. A method, comprising:
generating a register database, wherein the register database is configured to store one or more parameters of a plurality of registers, the plurality of registers representing the registers for a plurality of functional components on a system on chip (SoC);
receiving a design verification flow for verifying one or more of the plurality of functional components on the SOC;
generating a design verification script based on design verification flow;
converting the design verification script into a series of JTAG transactions; and
executing the series of JTAG transactions using a JTAG transactor.

2. The method of claim 1, wherein the JTAG transactor is configured on an emulator including a plurality of die-level emulators, one or more of the plurality of die-level emulators corresponding to one or more of the plurality functional components on the SOC.

3. The method of claim 2, further comprising:
generating an input test data (TDI) based on one or more of the JTAG transactions;
inputting the TDI into one of the plurality of die-level emulators; and
communicating the test data out (TDO) received from the one of the plurality die-level emulators to a design validation engine.

4. The method of claim 3, wherein the one or more of the plurality of die-level emulators are configured using FPGAs.

5. The method of claim 1, wherein generating a design verification script based on design verification flow using the register database further comprising generating instructions for one or more of read, write, and update to one of the plurality of registers in the register database.

6. The method of claim 1, wherein generating a design verification script based on design verification flow using the register database further comprising generating instructions for status check for one of the plurality of registers in the register database.

7. The method of claim 1, wherein converting the design verification script into a series of JTAG transactions further converting the design verification script into a series of JTAG transactions using a JTAG debugger.

8. The method of claim 1, wherein generating a design verification script based on design verification flow further comprising generating a design verification script based on design verification flow using the register database.

9. One or more physically manufactured computer-readable storage media, encoding computer-executable instructions for executing on a computer system a computer process, the computer process comprising:
generating a register database, wherein the register database is configured to store one or more parameters of a plurality of registers, the plurality of registers representing the registers for a plurality of functional components on a system on chip (SoC);
receiving a design verification flow for verifying one or more of the plurality of functional components on the SOC;
generating a design verification script based on design verification flow;
converting the design verification script into a series of JTAG transactions; and
executing the series of JTAG transactions using a JTAG transactor.

10. The one or more physically manufactured computer-readable storage media of manufacture of claim 9, wherein the JTAG transactor is configured on an emulator including a plurality of die-level emulators, one or more of the plurality of die-level emulators corresponding to one or more of the plurality functional components on the SOC.

11. The one or more physically manufactured computer-readable storage media of manufacture of claim 10, wherein the computer process further comprising:
generating an input test data (TDI) based on one or more of the JTAG transactions;
inputting the TDI into one of the plurality of die-level emulators; and
communicating the test data out (TDO) received from the one of the plurality of die-level emulators to a design validation engine.

12. The one or more physically manufactured computer-readable storage media of manufacture of claim 10, wherein the debugger module is configured to perform a mapping between the virtual register and a plurality of JTAG addresses on one or more of the plurality of functional blocks.

13. The one or more physically manufactured computer-readable storage media of manufacture of claim 10, wherein the one or more of the plurality of die-level emulators are configured using FPGAs.

14. The one or more physically manufactured computer-readable storage media of manufacture of claim 9, wherein generating a design verification script based on design verification flow using the register database further comprising generating instructions for one or more of read, write, and update to one of the plurality of registers in the register database.

15. The one or more physically manufactured computer-readable storage media of manufacture of claim 9, wherein generating a design verification script based on design verification flow using the register database further comprising generating instructions for status check for one of the plurality of registers in the register database.

16. A system comprising:
memory;
one or more processing units; and
a system on chip (SOC) design verification and emulation system stored in the memory and executable by the one or more processor units, the SOC design verification and emulation system encoding computer-executable instructions on the memory for executing on the one or more processor units a computer process, the computer process comprising:
generating a register database, wherein the register database is configured to store one or more parameters of a plurality of registers, the plurality of registers representing the registers for a plurality of functional components on a system on chip (SoC);
receiving a design verification flow for verifying one or more of the plurality of functional components on the SOC;
generating a design verification script based on design verification flow;
converting the design verification script into a series of JTAG transactions; and
executing the series of JTAG transactions using a JTAG transactor.

17. The system of claim 16, the JTAG transactor is configured on an emulator including a plurality of die-level emulators, one or more of the plurality of die-level emulators corresponding to one or more of the plurality functional components on the SOC.

18. The system of claim 17, wherein the computer process further comprising:
generating an input test data (TDI) based on one or more of the JTAG transactions;
inputting the TDI into one of the plurality of die-level emulators; and
communicating the test data out (TDO) received from the one of the plurality of die-level emulators to a design validation engine.

19. The system of claim 17, wherein generating a design verification script based on design verification flow using the register database further comprising generating instructions for one or more of read, write, and update to one of the plurality of registers in the register database.

20. The system of claim 17, wherein generating a design verification script based on design verification flow using the register database further comprising generating instructions for status check for one of the plurality of registers in the register database.
